(19) United States
(12) Patent Application Publication
(10) Pub. No.: US 2003/0143847 A1
(43) Pub. Date: Jul. 31, 2003

(54) Method of forming low dielectric constant insulating layer and method of manufacturing semiconductor device

(76) Inventors: Hideshi Miyajima, Kanagawa (JP); Miyoko Shimada, Ibaraki (JP); Rempei Nakata, Kanagawa (JP)

Correspondence Address: Finnegan, Henderson, Farabow,, Garrett & Dunner, L.L.P., 1300 I Street, N.W., Washington, DC, 20005-3315, US

(21) Appl. No.: 10/322,502

(22) Filed: Dec. 19, 2002

(30) Foreign Application Priority Data
Dec. 20, 2001 (JP) 2001-388109

(51) Int. Cl. H01L 21/302; H01L 21/461

(52) U.S. Cl. 438/689

(57) ABSTRACT

A method of forming a low dielectric constant insulating layer according to one aspect of the present invention includes: applying a material of low dielectric constant insulating layer containing a precursor of substances to constitute the low dielectric constant insulating layer or the substances above a substrate to be processed; and curing the material of low dielectric constant insulating layer by irradiating the material of low dielectric constant insulating layer with electron beams with the substrate to be processed being heated in a treatment chamber, the electron beams being incident on the material of low dielectric constant insulating layer from a direction different from a direction vertical to a surface of the material of low dielectric constant insulating layer above the substrate.

### CROSS-REFERENCE TO RELATED APPLICATIONS

This application is based upon and claims the benefit of priority from the prior Japanese Patent Application No. 2001-388109, filed on Dec. 20, 2001, the entire contents of which are incorporated herein by reference.

### BACKGROUND OF THE INVENTION

1. Field of the Invention

The present invention relates to a method of forming a low dielectric constant insulating layer, and a method of manufacturing a semiconductor device.

2. Related Background Art

As the wiring size of semiconductor devices is reduced due to the miniaturization of semiconductor devices, the inter-wire capacitance increases, which affects the operation speed of devices considerably. In order to achieve high-speed operation of a miniaturized device, the reduction in product of wire resistance and inter-wire capacitance is necessary. For this purpose, the employment of a low dielectric constant insulating layer to serve as an inter-layer insulating layer for reducing inter-wire capacitance, together with low-resistance copper wiring, is indispensable.

Conventionally, a silicon oxide layer formed by thermal CVD (Chemical Vapor Deposition) or plasma CVD has been used as an inter-layer insulating layer of a semiconductor device. However, in recent years, there have been demands for application of a low dielectric constant insulating layer made of an organic silicon oxide or an organic resin that contains no silicon to an inter-layer insulating layer.

The relative dielectric constant of a typical silicon oxide layer (P—SiO₂) obtained by conventional plasma CVD is about 4.1, and the relative dielectric constant of a low dielectric constant silicon oxide layer (FSG) obtained by adding fluorine (F) to the above-described silicon oxide layer is 3.3 or more. These values have been the limit values of the relative dielectric constant of an insulating layer formed by thermal CVD or plasma CVD. If a low dielectric constant insulating layer made of the above-mentioned organic silicon oxide or the like is used, a relative dielectric constant of about 2.4-3.0 can be achieved.

Generally, most low dielectric constant insulating layers made of an organic silicon oxide or an organic resin are formed by coating. Conventionally, such a low dielectric constant insulating layer of an organic silicon oxide or an organic resin has been formed by coating a substrate with a liquid material obtained by dissolving low molecular weight components, which constitute the material of the low dielectric constant insulating layer, in a solvent, and then by heating the coated substrate, thereby evaporating the solvent and cross-linking the low molecular weight component so as to form a thin film. Conventionally, heating has been performed by the use of an electric furnace or a hot plate, in which it takes from 30 to 60 minutes to complete the cross-linking reaction. Therefore, there has been a demand for a heating method by which a thin film can be formed in a shorter period of time.

In addition, there have been various problems in the practical application of such a low dielectric constant insulating layer. One critical problem is that the mechanical strength of a low dielectric constant insulating layer is low. Because of this, a crack may appear in a low dielectric constant insulating layer during the formation process or the subsequent machining process, or peeling may occur during the CMP (Chemical Mechanical Polishing) process. Thus, it has been difficult to make highly reliable wiring with low dielectric constant insulating layers.

### SUMMARY OF THE INVENTION

A method of forming a low dielectric constant insulating layer according to a first aspect of the present invention includes: applying a material of low dielectric constant insulating layer containing a precursor of substances to constitute the low dielectric constant insulating layer or the substances above a substrate to be processed; and curing the material of low dielectric constant insulating layer by irradiating the material of low dielectric constant insulating layer with electron beams with the substrate to be processed being heated in a treatment chamber, the electron beams being incident on the material of low dielectric constant insulating layer from a direction different from a direction vertical to a surface of the material of low dielectric constant insulating layer above the substrate.

A method of forming a low dielectric constant insulating layer according to a second aspect of the present invention includes: applying a material of low dielectric constant insulating layer containing a precursor of substances to constitute the low dielectric constant insulating layer or the substances above a substrate to be processed; and curing the material of low dielectric constant insulating layer by irradiating the material of low dielectric constant insulating layer with electron beams generated by an electron generating part with the substrate to be processed being heated in a treatment chamber, an electric field reducing a speed of the electron beams being applied between the electron generating part and the substrate to be processed.

A method of manufacturing a semiconductor device according to a third aspect of the present invention includes: forming a low dielectric constant insulating layer, serving as an inter-layer insulating layer, above a semiconductor substrate, on which devices have been formed, in accordance with the above-described methods of forming a low dielectric constant insulating layer.

### BRIEF DESCRIPTION OF THE DRAWINGS

FIG. 1 is a flow chart showing the procedure of a method of forming a low dielectric constant insulating layer according to the first embodiment of the present invention.

FIG. 2 shows the structure of an electron beam irradiation unit used in the method of forming a low dielectric constant insulating layer according to the first embodiment.

FIG. 3 shows the structure of an electron beam irradiation unit used in a method of forming a low dielectric constant insulating layer according to the second embodiment of the present invention.

FIG. 4 shows the structure of an electron beam irradiation unit used in a conventional method of forming a low dielectric constant insulating layer.

### DESCRIPTION OF THE EMBODIMENTS

As the result of hard and intensive study, the present inventors proved that the reduction in heating time during the formation of a low dielectric constant insulating layer and the improvement in mechanical strength of such a low dielectric constant insulating layer can be achieved by simultaneously performing heating and irradiation of electron beams. This is disclosed in U.S. patent application Ser. No. 09/982003, the entire contents of this reference being incorporated herein by reference.

The effects of the use of electron beams in the formation of a low dielectric constant insulating layer are as follows: the cross-linking reaction is effectively accelerated since a high energy, which cannot be obtained only through thermal treatment, can be obtained by the irradiation of electron beams; the irradiation of electron beams helps in achieving effective cross-linking at a low temperature, thereby inhibiting the failure in cross-linking and the increase in holes caused by the thermal stress due to the rise and fall in temperature, resulting in that a layer having a high mechanical strength can be formed; and from the standpoint of molecular structure, cross-linking may be performed at cross-linking points which are different from cross-linking points in the thermal treatment, resulting in that it is possible to establish a molecular structure having a higher mechanical strength, which cannot be achieved in the thermal treatment.

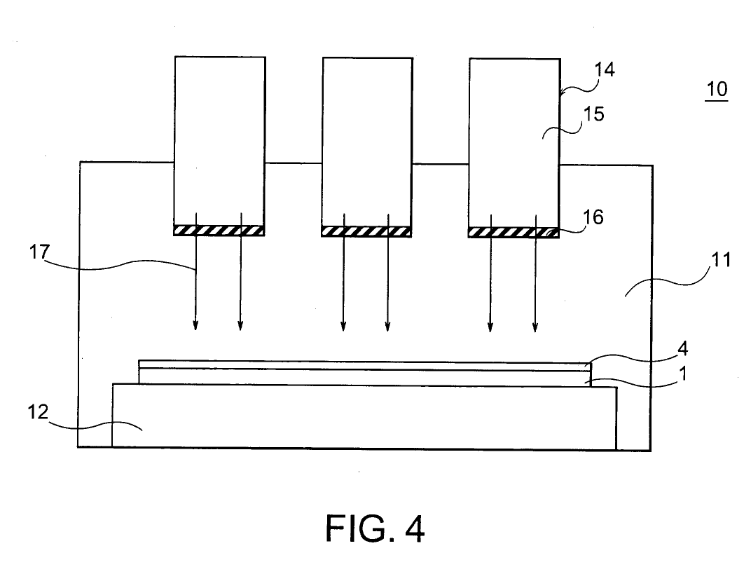

FIG. 4 shows the structure of an electron beam irradiation unit, which can be used for the above-described electron beam irradiation. In this electron beam irradiation unit 10, a plurality of electron tubes 14, each having an electron generating part 15, are placed in the upper part of a treatment chamber 11. Each electron generating part 15 is separated from the treatment chamber 11 by a partition wall 16. Electron beams 17 pass through the partition wall 16 to enter the treatment chamber 11. A hot plate 12 is placed in the bottom part of the treatment chamber 11 so as to face the electron tubes 14. A semiconductor substrate 1, on which a coating layer 4 is formed, is placed on the hot plate 12, and the semiconductor substrate 1 is irradiated with electron beams 17 under predetermined conditions.

In the electron beam irradiation unit 10, because of the existence of the partition walls 16, it is possible to inhibit the influence of gas evolved from the object to be irradiated. Thus, uniform irradiation of electron beams 17 from the electron generating parts 15 can be achieved, resulting in that the variation in characteristics of layers after the heating process can be minimized.

Thus, it is possible to achieve the reduction in heating time and the improvement in mechanical strength of the low dielectric constant insulating layer by simultaneously performing heating and irradiation of electron beams. However, in consideration of the damage to the partition walls 16 from electron beams, and the electron transmission efficiency at the partition walls 16, the electron generating part 15 is required to generate electron beams having the energy of more than about 20 keV. However, the present inventors have found that if an object is irradiated with electron beams having such energy, damage may be caused on a gate insulating layer of an MOSFET formed on an underlying layer.

Hereinafter, embodiments of the present invention, which have been improved with respect to the above-described problem, will be specifically described with reference to the accompanying drawings.

(First Embodiment)

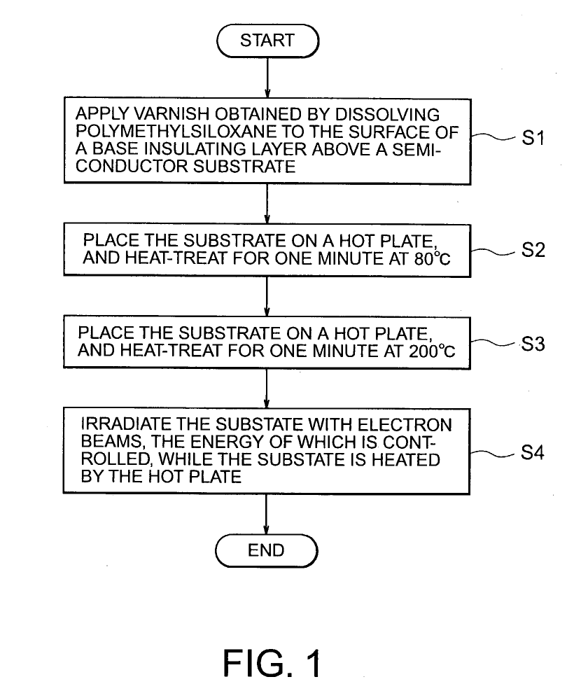

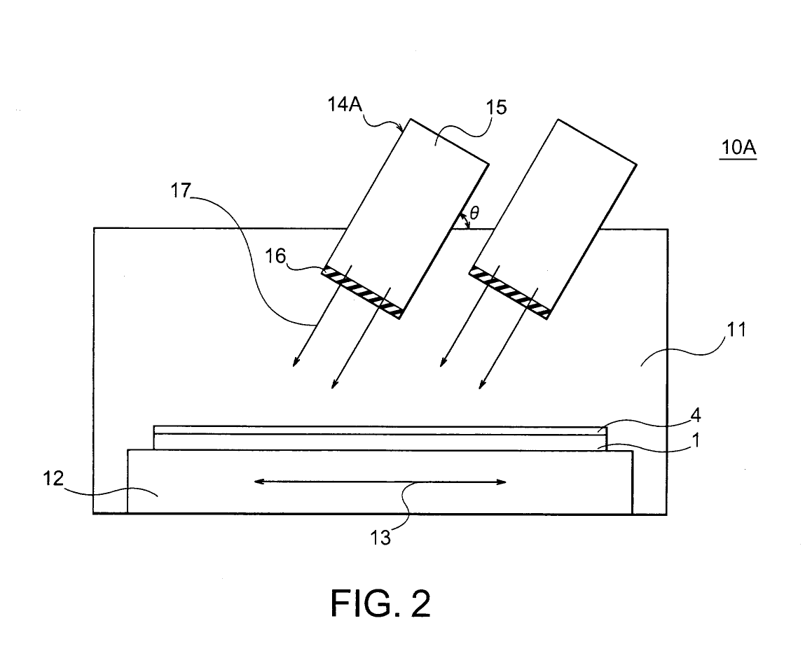

A method of forming a low dielectric constant insulating layer according to the first embodiment of the present invention will be described with reference to FIGS. 1 and 2. FIG. 1 is a flow chart showing the procedure of a method of forming a low dielectric constant insulating layer according to this embodiment. FIG. 2 shows the structure of an electron beam irradiation unit 10A used in the forming method of this embodiment.

First, a base insulating layer to be an underlying layer is formed on the surface of a semiconductor substrate, on which devices are integrated. Varnish 4, obtained by dissolving polymethylsiloxane, which contains Si, O, C, and H as main components and serves as a precursor of the material of the low dielectric constant insulating layer, in a solvent, is applied on the surface of the base insulating layer by the use of a spin coater (Step S1 of FIG. 1). If it is possible to prepare varnish by dissolving the material of the low dielectric constant insulating layer itself in a solvent to form a uniform coating layer, the precursor is not necessarily used. The term “precursor” means substances in the previous stage of a final product (in this case, a low dielectric constant insulating layer) herein.

Next, the substrate 1 is placed on a hot plate having been heated to maintain the temperature of 80° C., and treated with heat for one minute (Step S2 of FIG. 1). Then, the substrate 1 is placed on a hot plate having been heated to maintain the temperature of 200° C., and treated with heat for one minute (Step S3 of FIG. 1). Through Steps S2 and S3, the solvent is removed from the varnish applied to the substrate 1 in Step S1, so that a polymethylsiloxane layer 4 is fixed on the substrate 1.

Then, as shown in FIG. 2, the substrate 1 is placed on a hot plate 12, the temperature of which is maintained to be 350° C., in a treatment chamber 11 of the electron beam irradiation unit 10A, the treatment chamber 11 being in a reduced-pressure atmosphere. Subsequently, the substrate 1 is irradiated with electron beams 17, the energy of which is controlled, thereby curing the polymethylsiloxane layer 4 to form a low dielectric constant inter-layer insulating layer having a thickness of 1 μm (Step S4 of FIG. 1). When Step S4 is carried out, the oxygen concentration is restrained to be 100 ppm or less so that the surface of the coating layer 4 is not oxidized by oxygen contained in the atmosphere of the treatment chamber 11. For example, nitride gas, a noble gas, or a mixed gas containing nitride gas and a noble gas, which has an oxygen concentration of 100 ppm or less, is inserted into the electron beam irradiation unit 10A shown in FIG. 2 to perform Step S4.

In the electron beam irradiation unit 10A shown in FIG. 2, electron tubes 14A, each having an electron generating part 15, are placed in the upper part of the treatment chamber 11 so as to make an angle of θ with the horizontal plane. Each electron tube 14A has a partition wall 16. Electron beams 17 pass through the partition wall 16 to enter the treatment chamber 11. In the lower part of the treatment chamber 11, the hot plate 12 is placed so that the coating layer 4 formed on the substrate 1 mounted on the hot plate 12 is irradiated with electron beams from the electron generating parts 15.

Next, the electron beams, the energy of which is controlled, will be described below. The semiconductor substrate 1, on which the coating layer 4 had been formed, was mounted on the hot plate 12 of the electron beam irradiation unit 10A. The coating layer 4 was exposed to the electron beams 17 with an acceleration voltage of 25 keV, and an exposure dose of 500 μC/cm² in the reduced-pressure atmosphere of 10 Torr (=10×133.322 Pa), with the above-described angle θ being changed to be 30°, 60°, and 90°. The characteristics of low dielectric constant inter-layer insulating layers thus formed will be described below.

The relative dielectric constant of the insulating layers thus obtained was measured by the mercury probe method. As the result, the relative dielectric constant was about 3.0 regardless of the angle θ. Further, the modulus of elasticity was measured by the nano-indentation method. As the result, the modulus of elasticity was about 12 Gpa regardless of the angle θ. This value is about 1.5 times higher than the modulus of elasticity of an insulating layer obtained by the conventional method, i.e., obtained only by heat treatment. Generally, the greater the value of modulus of elasticity is, the less the peeling ratio in the CMP process is, i.e., the more resistance the insulating layer has to the formation of cracks and scratches.

In Step 4 of this embodiment, the temperature of the hot plate is 350° C., while in the conventional method using only the heat treatment, the temperature is 400° C. Accordingly, this embodiment can be carried out in a temperature 50° C. lower than that of the conventional method. Such a lower temperature is effective against the problem of peeling off the layer caused by the growth of crystal grains of copper (Cu) used for the wiring, or the problem of Cu migration. In Step S4 of this embodiment, the temperature of the hot plate 12 may be 200° C. or more and less than 500° C. In addition, the reduced-pressure atmosphere of the treatment chamber 11 may be less than 400 Torr.

The time required for carrying out Step S4 of this embodiment is from 2 to 10 minutes, which is a fifteenth to a third of the time required for carrying out the conventional heating process using a hot plate.

The damage to the gate insulating layer of a semiconductor device (MOSFET) caused by the irradiation of electron beams were examined. There was a shift in threshold voltage when the angle θ was 90°. However, there was no shift in threshold voltage and no damage to the gate insulating layer when the angle θ was 30° or 60°. The reason for this may be that as shown in FIG. 2, the energy of the electron beams 17 incident on the coating layer 4 was controlled to reduce the effective energy by placing the electron tubes 14A at an angle θ, thereby preventing the damage of the irradiation of electron beams to the gate insulating layer. Another reason may be that the direction of the momentum of the electron beams 17 incident on the coating layer 4 was controlled.

Further, in this embodiment, the in-plane uniformity of the thickness of the low dielectric constant inter-layer insulating layer was improved by about 50% by moving the hot plate 12 in the horizontal plane, as shown by an arrow 13 in FIG. 2, during the irradiation of electron beams in Step S4. When Step S4 was carried out with the hot plate 12 unmoved, the fluctuations in the in-plane uniformity of the-thickness, represented by 3σ (where σ is standard deviation) was about 3%. However, when the hot plate 12 was moved in the horizontal plane, 3σ was improved to be 1.5%. When the hot plate is moved in the horizontal plane, it is preferable that the hot plate is moved not only forward, backward, rightward, and leftward, but rotationally moved so that the incident directions of the electron beams 17 incident on the coating layer 4 are evenly changed during the irradiation.

As described above, in this embodiment, the electron tubes 14A are placed at an angle θ, so that the energy and the direction of momentum of the electron beams incident on the coating layer 4 are controlled to reduce the effective energy thereof. Accordingly, it is possible to form a low dielectric constant insulating layer having a high mechanical strength without causing damage to the layers underneath.

The angle θ at which the electron tubes 14A are placed may be 30° or more and 80° or less in order to effectively reduce the effective energy of the electron beams 17. Further, the same effects as described above can be obtained if at least one or both of the energy and the direction of momentum of the electron beams incident on the coating layer 4 is controlled.

In addition, it is possible to manufacture a semiconductor device having a low dielectric constant insulating layer with a high mechanical strength if the low dielectric constant insulating layer, which serves as an inter-layer insulating layer, is formed on a semiconductor substrate, on which devices are formed, by using the method of forming a low dielectric constant insulating layer according to this embodiment.

(Second Embodiment)

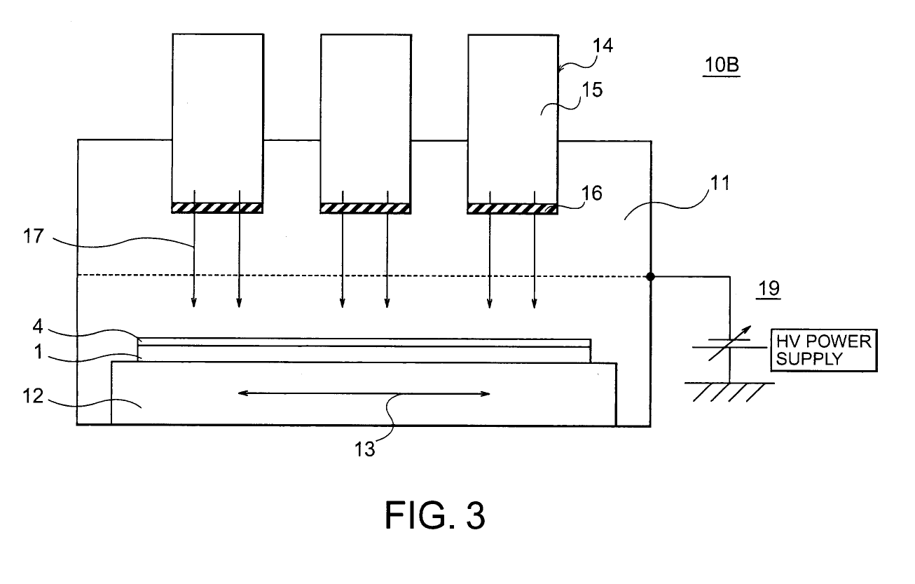

Next, a method of forming a low dielectric constant insulating layer according to the second embodiment of the present invention will be described. This embodiment includes Steps S1 to S4 shown in FIG. 1, as in the case of the first embodiment, but the method of controlling the energy of the electron beams is different from that of the first embodiment. FIG. 3 shows the structure of an electron beam irradiation unit 10B used in this embodiment. The electron beam irradiation unit 10B is obtained by adding an electric field applying device 19 to the electron beam irradiation unit 10 shown in FIG. 4. The electric field applying device 19 applies an electric field to the electron beams 17 having passed through the partition wall 16 to enter the treatment chamber 11 so as to reduce the speed of the electron beams 17 when they are incident on the coating layer 4. As the electric field applying device 19 reduces the speed of the electron beams 17 incident on the coating layer 4, the energy of the electron beams 17 is reduced.

The semiconductor substrate 1, on which the coating layer 4 had been formed, was placed on the hot plate 12 in the electron beam irradiation unit 10B. Then the coating layer 4 was exposed to electron beams with an acceleration voltage of 25 keV, and an irradiation dose of 500 μmC/cm² in the reduced-pressure atmosphere of 10 Torr (10×133.322 Pa) with a reverse electric field being either applied or not applied. The characteristics of low dielectric constant inter-layer insulating layers thus obtained will be described below.

The relative dielectric constant of the insulating layers thus obtained was measured by the mercury probe method. In both cases, the relative dielectric constant was about 3.0. Further, the modulus of elasticity was measured by the nano-indentation method. As the result, the modulus of elasticity in both cases was about 15 Gpa.

Further, as in the case of the first embodiment, the temperature of the hot plate in Step S4 of this embodiment is 350° C., which is 50° C. lower than 400° C. of the conventional method using only heat treatment. Such lower temperature is effective against the problem of peeling off the layer, caused by the growth of crystal grains of copper (Cu) used for the wiring, or the problem of Cu migration. In Step S4 of this embodiment, the temperature of the hot plate 12 may be 200° C. or more and less than 500° C. In addition, the reduced-pressure atmosphere of the treatment chamber 11 may be less than 400 Torr.

The time required for carrying out Step S4 of this embodiment is from 2 to 5 minutes, which is a fifteenth to a sixth of the time required for carrying out the conventional heating process using a hot plate.

The damage to the gate insulating layer of a semiconductor device (MOSFET) caused by the irradiation of electron beams were examined. There was a shift in threshold voltage when no reverse electric field was applied. However, there was no shift in threshold voltage and no damage to the gate insulating layer when the reverse electric field was applied. The reason for this may be that the energy of the electron beams incident on the coating layer 4 was reduced, thereby preventing damage to the gate insulating layer.

Further, in this embodiment, the in-plane uniformity of the thickness of the low dielectric constant inter-layer insulating layer was improved by about 50% by moving the hot plate 12 in the horizontal plane during the process in Step S4. When Step S4 was carried out with the hot plate 12 unmoved, 3σ of the in-plane uniformity of the thickness was about 3%. However, when the hot plate 12 was moved, 3σ was improved to be 1.5%.

As described above, in this embodiment, the energy of the electron beams 17 incident on the coating layer 4 is controlled by applying a reverse electric field to the electron beams 17 passing through the partition wall 16 to enter the treatment chamber 11. Accordingly, it is possible to form a low dielectric constant insulating layer having high mechanical strength without causing damage to the underlying layers.

In addition, it is possible to manufacture a semiconductor device having a low dielectric constant insulating layer having high mechanical strength if the low dielectric constant insulating layer, which serves as an inter-layer insulating layer, is formed on a semiconductor substrate, on which devices are formed, by using the method of forming a low dielectric constant insulating layer according to this embodiment.

Thus, according to the embodiments of the present invention, it is possible to form a low dielectric constant insulating layer having high mechanical strength without causing damage to the layers underneath.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A method of forming a low dielectric constant insulating layer, comprising:
applying a material of low dielectric constant insulating layer containing a precursor of substances to constitute the low dielectric constant insulating layer or the substances above a substrate to be processed; and
curing the material of low dielectric constant insulating layer by irradiating the material of low dielectric constant insulating layer with electron beams with the substrate to be processed being heated in a treatment chamber,
the electron beams being incident on the material of low dielectric constant insulating layer from a direction different from a direction vertical to a surface of the material of low dielectric constant insulating layer above the substrate.

2. The method of forming a low dielectric constant insulating layer according to claim 1, wherein the substrate to be processed is placed on a table, which is movable in a horizontal direction, and the material of low dielectric constant insulating layer is irradiated with the electron beams while the table is horizontally moved.

3. The method of forming a low dielectric constant insulating layer according to claim 1, wherein a temperature of the substrate to be processed is maintained to be 200° C. or more and less than 500° C.

4. The method of forming a low dielectric constant insulating layer according to claim 1, wherein the applying the material of low dielectric insulating layer includes:
applying varnish, which is obtained by dissolving the material of low dielectric constant insulating layer in a solvent above the substrate to be processed; and
removing the solvent by heat treatment.

5. The method of forming a low dielectric constant insulating layer according to claim 1, wherein the irradiation of the electron beams is performed in an atmosphere whose oxygen concentration is 100 ppm or less.

6. The method of forming a low dielectric constant insulating layer according to claim 1, wherein the electron beams are incident on the surface of the material of low dielectric constant insulating layer at an angle of 30° or more and 80° or less.

7. A method of forming a low dielectric constant insulating layer comprising:
applying a material of low dielectric constant insulating layer containing a precursor of substances to constitute the low dielectric constant insulating layer or the substances above a substrate to be processed; and
curing the material of low dielectric constant insulating layer by irradiating the material of low dielectric constant insulating layer with electron beams generated by an electron generating part with the substrate to be processed being heated in a treatment chamber,
an electric field reducing a speed of the electron beams being applied between the electron generating part and the substrate to be processed.

8. The method of forming a low dielectric constant insulating layer according to claim 7, wherein the substrate to be processed is placed on a table, which is movable in a horizontal direction, and the material of low dielectric constant insulating layer is irradiated with the electron beams while the table is horizontally moved.

9. The method of forming a low dielectric constant insulating layer according to claim 7, wherein a temperature of the substrate to be processed is maintained to be 200° C. or more and less than 500° C.

10. The method of forming a low dielectric constant insulating layer according to claim 7, wherein the applying the material of low dielectric insulating layer includes:
applying varnish, which is obtained by dissolving the material of low dielectric constant insulating layer in a solvent above the substrate to be processed; and
removing the solvent by heat treatment.

11. The method of forming a low dielectric constant insulating layer according to claim 7, wherein the irradiation of the electron beams is performed in an atmosphere whose oxygen concentration is 100 ppm or less.

12. A method of manufacturing a semiconductor device comprising:
forming a coating layer made of a material of low dielectric constant insulating layer containing a precursor of substances to constitute a low dielectric constant insulating layer or the substances above a semiconductor substrate, on which devices have been formed; and
curing the material of low dielectric constant insulating layer by irradiating the coating layer made of the material of low dielectric constant insulating layer with electron beams with the semiconductor substrate being heated in a treatment chamber, thereby forming an inter-layer insulating layer,
the electron beams being incident on the coating layer made of the material of low dielectric constant insulating layer from a direction different from a direction vertical to a surface of the coating layer made of the material of low dielectric constant insulating layer.

13. The method of manufacturing a semiconductor device according to claim 12, wherein the semiconductor substrate is placed on a table, which is movable in a horizontal direction, and the coating layer made of the material of low dielectric constant insulating layer is irradiated with the electron beams while the table is horizontally moved.

14. The method of manufacturing a semiconductor device according to claim 12, wherein a temperature of the semiconductor substrate is maintained to be 200° C. or more and less than 500° C.

15. The method of manufacturing a semiconductor device according to claim 12, wherein the irradiation of the electron beams is performed in an atmosphere whose oxygen concentration is 100 ppm or less.

16. The method of manufacturing a semiconductor device according to claim 12, wherein the electron beams are incident on the surface of the coating layer made of the material of low dielectric constant insulating layer at an angle of 30° or more and 80° or less.

17. A method of manufacturing a semiconductor device comprising:
forming a coating layer made of a material of low dielectric constant insulating layer containing a precursor of substances to constitute a low dielectric constant insulating layer or the substances above a semiconductor substrate, on which devices have been formed; and
curing the material of low dielectric constant insulating layer by irradiating the coating layer made of the material of low dielectric constant insulating layer with electron beams generated by an electron generating part with the semiconductor substrate being heated in a treatment chamber, thereby forming an inter-layer insulating layer,
an electric field reducing a speed of the electron beams being applied between the electron generating part and the semiconductor substrate.

18. The method of manufacturing a semiconductor device according to claim 17, wherein the semiconductor substrate is placed on a table, which is movable in a horizontal direction, and the coating layer made of the material of low dielectric insulating layer is irradiated with the electron beams while the table is horizontally moved.

19. The method of manufacturing a semiconductor device according to claim 17, wherein a temperature of the semiconductor substrate is maintained to be 200° C. or more and less than 500° C.

20. The method of manufacturing a semiconductor device according to claim 17, wherein the irradiation of the electron beams is performed in an atmosphere whose oxygen concentration is 100 ppm or less.
